(19) United States
(12) Patent Application Publication
(10) Pub. No.: US 2025/0334875 A1
(43) Pub. Date: Oct. 30, 2025

(54) EXTREME ULTRAVIOLET PELLICLE WITH ENHANCED EXTREME ULTRAVIOLET TRANSMISSION AND METHOD OF PRODUCING THEREOF

(71) Applicant: LINTEC OF AMERICA, INC., Plano, TX (US)

(72) Inventors: Marcio D. LIMA, Richardson, TX (US); Takahiro UEDA, Tsukuba City (JP); Sergey LI, McKinney, TX (US); Hooman RAHMANI, Plano, TX (US)

(73) Assignee: LINTEC OF AMERICA, INC., Plano, TX (US)

(21) Appl. No.: 18/877,519

(22) PCT Filed: Jun. 20, 2023
(86) PCT No.: PCT/US2023/025715

§ 371 Date: Dec. 20, 2024

Related U.S. Application Data
(60) Provisional application No. 63/353,908, filed on Jun. 21, 2022.
(60) Provisional application No. 63/444,011, filed on Feb. 8, 2023.

(51) Int. Cl. G03F 1/62; B82Y 30/00; B82Y 40/00

(52) U.S. Cl. CPC G03F 1/62; B82Y 30/00; B82Y 40/00

(57) ABSTRACT

A method of enhancing extreme ultraviolet (EUV) transmission and reducing scattering of a carbon nanostructure pellicle film is disclosed. The method includes annealing the carbon nanostructure pellicle film at least once at an elevated temperature before exposing the pellicle film to an EUV lithography process. The method further provides measures to maintain the annealed nanostructure pellicle film in an inert gas environment or vacuum.

### CROSS-REFERENCE TO RELATED PATENT APPLICATIONS

This application claims priority to U.S. Provisional Patent Application No. 63/353,908, filed on Jun. 21, 2022, and U.S. Provisional Patent Application No. 63/444,011 filed on Feb. 8, 2023. The disclosure of each of these documents, including the specification, drawings, and claims, is hereby incorporated by reference in its entirety for all purposes.

### TECHNICAL FIELD

This disclosure generally relates to a modified thin film and a thin film device used in a semiconductor microchip fabrication, and more particularly to an ultra-thin, ultra-low density, nanostructured free-standing pellicle film with a film treatment, said film and film device destined for extreme ultraviolet (EUV) lithography.

### BACKGROUND

A pellicle is a protective device that covers a photomask and is used in semiconductor microchip fabrication. The photomask may refer to an opaque plate with holes or transparencies that allow light to shine through in a defined pattern. Such photomasks may be commonly used in photolithography and the production of integrated circuits. As a master template, the photomask is used to produce a pattern on a substrate, normally a thin slice of silicon known as a wafer in the case of semiconductor chip manufacturing.

Particle contamination is often a significant problem in semiconductor manufacturing. It becomes a more prominent issue in advanced photolithography of much high resolution processes, affecting product yields as any nonegligible particles may alter the printing patterns of logic circuits on the chips, which have no built-in redundancy.

A photomask is protected from particles by a pellicle, a thin transparent film stretched over a frame (also referred to as a pellicle border with a central opening) that is attached over the patterned side of the photomask. The pellicle is close to but far enough away from the mask so that moderate-to-small-sized particles that land on the pellicle will be too far out of focus to print. However, fall-on particles are still observed after a period of exposure usage with unknown particle sources, according to field reports in the semiconductor industry,

Recently, the microchip manufacturing industry realized that the pellicle might also protect the photomask from damage stemming from causes other than particles and contaminants.

Extreme ultraviolet (EUV) lithography is an advanced optical lithography technology using a range of EUV wavelengths, more specifically, about 13.5 nm wavelength. The EUV lithography enables semiconductor microchip manufacturers to pattern the most sophisticated features at 7 nm resolution and beyond and place many more transistors without increasing the size of the required space. EUV photomasks work by reflecting light, which is achieved by using multiple alternating layers of molybdenum and silicon. When an EUV light source turns on, the EUV light hits the pellicle film first, passes through the pellicle film, and then bounces back from underneath the photomask, hitting the pellicle film once more before it continues its path to print a microchip. Some of the energy is absorbed during this process, and heat may be generated, absorbed, and accumulated as a result. The temperature of the pellicle may heat up to anywhere from 500° Celsius to 1000° Celsius or above.

While heat resistance is important, the pellicle must also be highly transparent for EUV transmission to ensure the passing through of the reflected light and light pattern from the photomask. This is one of the main reasons that EUV pellicles are generally very thin, less than 200 nm, preferably less than 100 nm, or less than 40 nm in thickness.

In 2016, a polysilicon-based EUV pellicle was developed after decades of research and effort with only 78% EUV transmission on a simulated relatively low-power 175-watt EUV source. Due to greater transistor density demand, stringent requirements present further technical challenges to EUV pellicle developers for a higher transmission rate, lower transmission variation, higher temperature tolerance, and strong mechanical strength.

Attempts have been made to target a high light transmittance rate by deploying a high carbon nanotube content in a carbon nanotube sheet (e.g., as high as 99% by mass). Such attempts have resulted in a product that may also meet mechanical strength and/or durability of the pellicle film requirements based on current industry standards. Further improvements include fulfilling more stringent standards, improving user experience, lowering production costs, and creating financial benefits. Accordingly, such carbon nanotube-based thin film has to provide a certain level of thickness to support its structural integrity. As a result, EUV transmission of such carbon nanotube-based thin films may require compromise when dealing with thicker films. Therefore, techniques beyond conventional technology and knowledge to accommodate both the transmission of EUV light and the thickness of the pellicle film have been sought and created to make further progress.

An attempt to produce ultra-thin, ultra-low density Carbon nanotube (CNT) pellicle membrane hit its milestone as published in WO 2021/090699. In this application, an ultra-thin film (about 3 nm thick) with a size as large as the current industry standards was achieved. However, such ultra-thin films, as thin as about 3 nm, present practical challenges since they are prone to damage during product packaging, shipping and handling, and human and robotic maneuvers.

Accordingly, alternative film treatment methods are sought to create freight-friendly pellicles while maintaining ultra-thin and/or, ultra-EUV transparent features.

### SUMMARY

According to an aspect of the present disclosure, a specifically structured nanostructure film is disclosed. The nanostructure film includes a plurality of carbon nanofibers that are intersected randomly to form an interconnected network structure in a planar orientation, the intersected or interconnected network structure having a thickness ranging from a lower limit of 3 nm to an upper limit of 100 nm, and a light transmission rate from 50% to above 95% at 550 nm wavelength and a EUV transmission rate from 75% to above 94%, up to 99%, in which the nanostructure film (e.g., nanofiber structure) undergoes an annealing process, preferably thermal annealing. The preferred CNT pellicles have the plurality of carbon nanofibers with at least 50% of double-walled carbon nanofibers, at least 50% of single-walled carbon nanofibers, or at least 50% of three or more walled carbon nanofibers, with the rest filled with carbon nanofibers with different number-walled carbon nanofibers to account for the final 100% content. The present disclosure further includes CNT pellicle films with any combination of single-walled, double-walled, and multi-walled carbon nanotubes and other types of nanofiber. Such nanofiber structures may present a further enhanced EUV transmission upon the contemplated annealing treatment, turning non-EUV lithography compatible or less EUV transmittable nanofiber film structure into a EUV lithography-eligible membrane or pellicle, meeting the industrial requirement and standards.

According to another aspect of the present disclosure, an annealing chamber may have one or more gases flowing through during annealing.

According to another aspect of the present disclosure, in some embodiments, annealing treatment enhances EUV transmission rate and/or reduces EUV scattering.

According to a further aspect of the present disclosure, in some embodiments, annealing treatment raises a EUV transmission rate of a nanofiber structure from below 95% to above 95%, or even below 90% to above 90% or above 95%. The difference in EUV transmission rates before or after the annealing is greater than 0.3%, 1.0%, 2.0%, greater than 5.0%, or greater than 10.0%.

According to yet another aspect of the present disclosure, in some embodiments, an annealing treatment means applying electromagnetic irradiations directly or indirectly to pellicle films or pellicle devices that include pellicle films on their frames. Exemplary electromagnetic irradiation light source includes, but is not limited to, electromagnetic waves in a spectrum of visible light, laser light, infrared, ultraviolet, radio wave, X-ray, and physical deposition, e.g., electron beam deposition.

According to yet another aspect of the present disclosure, in some embodiments, the annealing treatment may involve thermal annealing by placing the nanofiber structures in a chamber and heating the chamber to 600 degrees Celsius for 10 minutes.

According to one aspect of the present disclosure, in some embodiments, the thermal annealing temperature may be 500° C. and above, preferably 600° C., 650° C., 700° C., 800°° C., or 1,000° C. and above.

According to yet another aspect of the present disclosure, the annealing chamber may be a vacuum chamber, a chamber with reduced pressure, or a chamber having a gas or two or more gases passing through.

According to one aspect of the present disclosure, the vacuum chamber may be a part of a EUV scanner or have direct connections with a EUV scanner, such as within a lithography machine or lithography system or a semiconductor manufacturing production line, for delivery of freshly annealed pellicle films or pellicle devices to scanners.

According to another aspect of the present disclosure, thermal annealing on pellicle films or pellicle devices may occur remotely from EUV scanners or actual semiconductor production sites.

According to one aspect of the present disclosure, the thermal annealing of a pellicle membrane is performed before EUV irradiation with no or limited atmospheric air exposure or no or limited other non-inert gas exposure.

According to yet another aspect of the present disclosure, thermal annealing of a pellicle film or pellicle device may be performed in a non-vacuum chamber or a chamber under a reduced atmospheric pressure filled with one or more selected inert gases. Exemplary inert gases include, but are not limited to, argon, helium, neon, krypton, xenon, and radon.

According to another aspect of the present disclosure, the nanostructured film has an areal density of about 0.2 μg/cm² to about 6.0 μg/cm².

According to an aspect of the present disclosure, a pellicle is disclosed. The pellicle includes a pellicle border defining an aperture, at least one nanostructured film mounted to the pellicle border covering the aperture, said pellicle film being annealed or thermally annealed anytime prior to receipt of EUV radiation.

According to one aspect of the present disclosure, a method of producing a pellicle film or a pellicle device for EUV lithography is disclosed. The method includes steps of producing a pellicle film, preferably by filtration method, mounting the pellicle film to a pellicle border or an intermediary border, annealing a pellicle at a high temperature, and optionally transferring a pellicle film from the intermediary border onto a pellicle border.

According to another aspect of the present disclosure, a method of performing EUV lithography is disclosed. The method includes steps of annealing a pellicle at a high temperature and then transmitting EUV radiation through the pellicle.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a filtration method for forming a pellicle film followed by an annealing step with an optional transferring step in accordance with an exemplary embodiment.

FIG. 2 illustrates a scanning electron microscope (SEM) image of a microstructure of a double-wall CNT (DWCNT)-dominant film in accordance with an exemplary embodiment.

FIG. 3 illustrates a correlation between areal densities of CNT nanostructure films and their light transmission rates measured at 550 nm in accordance with an exemplary embodiment.

FIG. 4 illustrates Fourier-transform infrared (FTIR) spectra of CNT membranes before and after annealing treatments in accordance with exemplary treatment regimens in accordance with an exemplary embodiment.

FIG. 5 illustrates the transmittance data of CNT membranes from different exemplary treatment regimens in accordance with an exemplary embodiment.

FIG. 6 illustrates the transmittance data of CNT membranes measured at different time points post-explanatory annealing treatment in accordance with an exemplary embodiment.

FIG. 7 illustrates the transmittance changes of CNT membranes by different annealing durations in accordance with an exemplary embodiment.

### DETAILED DESCRIPTION

Through one or more of its various aspects, embodiments and/or specific features, sub-components, or processes of the present disclosure are intended to bring out one or more of the advantages as specifically described above and noted below.

A pellicle may refer to a thin transparent membrane that protects a photomask during semiconductor microchip production. The pellicle contemplates a protective device with a) a border or a frame and 2) a central opening or aperture. Both border and aperture are covered by a continuous thin film on the top of at least a portion of the border and a portion of the aperture, preferably the entire circumference of the border and the entire aperture. The center portion of such a thin film extending the aperture is free-standing. The pellicle may act as a dust cover or a filter that prevents particles and contaminants from falling onto the photomask during production. However, the pellicle must be sufficiently transparent to allow the light transmission necessary to perform lithography. Higher light transmission is desired for more effective lithography. For most EUV lithography applications, a 90% EUV transmission rate from a pellicle may be sufficient. The high-resolution EUV lithography at 5 nm or below, a high-energy EUV scanner, or a high numeric aperture EUV lithography scanner may prefer a EUV transmission rate of 90% or above, 92% or above, 94% or above, 96% or above, up to 99%.

Further, pellicles for EUV lithography require a large (e.g., greater than 110×140 mm) free-standing, thin-film material with extreme and unique properties. Besides high transparency to EUV radiation, any unexpected EUV transmission variation may cause detrimental effects during manufacturing processes, leading to faulty printing results, aberrant printing patterns, lower production yields, etc. And EUV pellicle films may be required to be resistant to temperatures above 400° C. and mechanically robust to survive handling, shipping, and pumping down and venting operations during the photolithographic process. A mechanically weak pellicle film may 1) deflect or sag during scanner chamber pressure changes, causing the damages of pellicle films themselves, such as slits or wrinkles; 2) contact with underlying photomasks, leading to erroneous printing images; and 3) break to contaminate the scanner chamber. Pellicle film's gas permeability but with a capacity to retain micrometer-sized particles is also desired. Given the number of high-level properties required, effective EUV pellicles have been conventionally difficult to produce.

In this aspect, carbon nanotubes and equivalent nanofibers have been suggested as possible starting materials to create pellicles for this EUV pellicle application due to their excellent thermal and mechanical properties and capability to form porous films.

### Carbon Nanotubes and Carbon Nanotube Films

Carbon nanotubes (CNTs) or carbon nanofibers, as often referred to herein, are long tubes with small diameters typically measured in nanometers. They have a high aspect ratio of length vs. diameter in a range generally preferred above about 100:1, which may be above about 1000:1. Another preferred aspect ratio may be at least approximately 10,000:1. CNTs are made up of one or more graphene sheets rolled up into a concentric structure. Each graphene sheet is regarded as a wall of a CNT. A single-wall CNT (SWCNT) is made of a single graphene sheet. A double-wall CNT (DWCNT) is made of two graphene sheets. Lastly, a multiwall CNT (MWCNT) has multiple graphene sheets. Other types of CNTs may include, but are not limited to, coaxial nanotubes, conical carbon nanotubes, and closed carbon nanotubes. Other carbon allotropes may also form sheets with excellent properties for pellicle films. For CNTs, they may exist substantially pure in one type or often in combination with other types with respect to the number of CNT walls. The CNTs may also exist individually, separated from others, or form bundles. A bundle may include the same type or different types of CNTs, such as SWCNT with DWCNT, SWCNT with MWCNT, etc. Within a bundle, CNTs may have different lengths and diameters. Each bundle, having two or more CNTs, may be aligned in parallel, at least for a portion of their entire lengths. For simplicity and convenience, CNTs in this application may refer to different types of CNTs, for example, different numbers of walls, and include CNTs existing individually or in bundles.

As used herein, nanofiber may exemplarily refer to a fiber having a diameter of less than 1 μm. Nanofiber and nanotube are used interchangeably and may encompass SWCNTs, DWCNTs, MWCNTs, and other carbon allotropes in which carbon atoms are linked together to form a cylindrical structure.

An individual CNT may be intersected with one or more other CNTs. Together, many CNTs could form a mesh-like microstructure film. One exemplary embodiment may include a free-standing microstructure thin film, of which an area of the thin film has no supporting material or substrate on either side of the thin film. While such formation is possible, it may not be guaranteed in every trial, especially for making an ultra-thin film with high transparency and other properties intended for EUV lithography pellicles.

Further, among several possible methods to fabricate free-standing films, a filtration-based approach was utilized to produce membrane films from small-size films to sufficiently large films with uniform film thickness for EUV lithography. Films having a uniform thickness generally correlate to even light transmission. This filtration-based method allows for the quick manufacturing of films not only of CNTs but also other high aspect ratio nanoparticles and nanofibers, such as boron nitride nanotubes (BNNT) or silver nanowires (AgNW). Since this approach separates the nanotubes or nanoparticle syntheses and the film manufacturing processes, a variety of types of nanofibers produced by virtually any method may be used. Different types of nanotubes (SWCNT, DWCNT, MWCNT, or carbon allotropes) may be mixed in any desired ratio. As filtration can be a self-leveling process in the sense that non-uniformities of film thickness during the filtration process are self-corrected by the variations of local permeability and, therefore, a highly desirable film formation process, it is also a promising candidate for the production of highly uniform films.

### Annealing Treatment

Annealing refers to a process of applying a heat treatment to a material to alter the given material's physical and sometimes chemical properties to increase its ductility and reduce its hardness. Annealing starts with a heating source, administrates the heating energy onto a material to raise the temperature of such material from its ambient temperature to a predetermined temperature, holds the desired temperature for a preselected treatment duration, and then lets the material cool off.

The heating performed for annealing may be electrical heating, in which an electric current, voltage, and/or electrical energy are passed through a material by directly contacting the material.

Alternatively, heating performed for annealing may be convection heating. An exemplary convection heating flows a heated gas over the surface and/or sometimes the material interior passage and raises the target's temperature.

Another heating performed for annealing may be radiant heating, in which an electromagnetic wave is directed toward a targeted material. A light source within a visible spectrum, including a laser, can heat a target material by delivering radiation directly upon a target or target surface. The photons of the light may bounce, re-radiate, or scatter, which may cause uneven heating due to any topographical differences, features, and/or unevenness of a given area of the material. An environment carrying out such treatment and interfering with a light pathway toward a target may cause uneven annealing results. This unevenness brought by a direct light treatment becomes more prominent for an area receiving repetitive irradiation vs. irradiation avoidance areas if the entire material surface is not irradiated simultaneously. Furthermore, laser treatments may burn, ablate, or sublimate surface material. Even a trace amount of such “lifted” material generated by laser treatment, which could be in the form of small molecules or elements, may be reabsorbed or redeposited to an untreated or sometimes treated surface, thus, creating new unevenness or exacerbating existing non-uniformity of the film.

However, aspects of the present disclosure are not limited thereto, such that different heating operations/methods may be performed or a combination of heating operations may be performed.

Annealing may be thermal annealing, which may use an electromagnetic wave within a non-visible light spectrum, including but not limited to infrared (e.g., near, mid, and/or far infrared). Such electromagnetic wavelength may have a range selected from between about 10 nm to about 1 mm. A preferred range may also be selected from between about 400 nm to about 700 nm or between about 700 nm to about 1 mm. Yet another preferred wavelength may be between about 5 μm to about 20 μm. This heating method transfers energy to a target material while the thermal energy dissipates into other microscopic motions within a material. In other words, thermal annealing distributes its energy power and heats a target material to raise the temperature uniformly. This type of thermal annealing may cover the entire object regardless of the direction of the incoming energy source. Ceramic heating by a ceramic heating tube with sufficient inner space for the reception of full-size pellicles is one of many choices to implement invisible light spectrum-based thermal heating. The heating element may be made of silicon carbide and molybdenum disilicide. Without wishing to be bound by scientific theory, it is believed other heating elements and heating devices are also applicable.

In a heating tube, one or multiple heating sources or heating elements may be arranged in a circular array for a cross-section view or tubular arrangement with respect to the overall heating device shape. Electromagnetic waves from such a heating source will distribute radiation uniformly within the tubular chamber. With a proper electromagnetic wave spectrum and emitting sources, such annealing provides and ensures uniform radiation arriving at a CNT pellicle and covering the entire pellicle area at any given time during the process, thus, yielding the least or lower EUT transmission variation compared to non-whole film field annealing.

The annealing treatment in the exemplary embodiments includes, but is not limited to, the above-mentioned heating methods.

The common annealing temperature may be any temperature above an ambient temperature. It may be 50° C. and above, 100° C. and above, 300° C. and above, 500° C. and above, 600° C. and above, 650° C. and above, 700° C. and above, 800° C. and above, 900° C. and above, or 1,000° C. and above. It may also be 3,000° C. or less, 2,500° C. or less, 2,000° C. or less, 1,800° C. or less, 1,700° C. or less, 1,600° C. or less, 1,500° C. or less, or 1,400° C. or less. A heating temperature may be within a range of any two aforementioned temperatures.

Selecting an annealing temperature may require further consideration of other factors, such as a suitable temperature range depending on the material properties of pellicle borders, such as their thermal expansion property. A low thermal expansion property is preferred (e.g., quartz) for the pellicle border.

The annealing temperature may ramp up at a fixed or a variable speed, depending on the heating devices/methods utilized and heating devices' heating capabilities. A common and practical temperature climbing speed may be about 20° C./min. A preferred heating regimen heats CNT pellicles swiftly to avoid or limit potential CNT oxidation due to possible chemical contaminants adhered onto an annealing chamber or mixed in with a flow-through gas. A heating regimen may also have a balance with pellicle borders' physical and sometimes chemical properties and their thermal expansion to avoid cracking of the pellicle borders.

Post-annealing cooling may allow the elevated temperature to return to ambient conditions naturally. Alternatively, the post-annealing cooling process may flow a cooling gas, an ambient temperature gas, or a gas with descending temperature over a period of time to cool off the annealing chamber to avoid possible wrinkles and maintain the mechanical strength of the film. An inert gas is preferred hereof.

Annealing treatment may occur in a vacuum (e.g., vacuum annealing), partial vacuum, or at atmospheric pressure. Additionally, it may occur in the presence of an inert gas or non-inert gas, such as a hydrocarbon gas. Alternating between an inert gas(es) and hydrocarbon gas(es) input during annealing treatment may further enhance pellicle film properties, such as light transmittance, and increase the mechanical strength of the pellicle film.

Exemplary inert gases include, but are not limited to, argon, helium, neon, krypton, xenon, and radon. Exemplary hydrocarbon gases include but are not limited to methane, ethane, propane, butanes, pentanes, hexane, and heptane.

Gas may flow through the annealing chamber at a constant or variable flow rate. Two or more gas types as a gas mixture may flow through the annealing chamber at a constant or variable flow rate. Further, two or more gas types may flow continuously or intermittently. A gas or gas mixture may be preheated before being injected into an annealing chamber for convection heating and/or be actively heated while inside an annealing chamber. A gas or gas mixture may be purposely selected and injected during annealing. For example, applying a hydrocarbon gas has been previously reported to repair structural defects of nanofibers and nanoparticle formation on the pellicle film surfaces. Due to the nature of working with ultra-thin, ultra-low density film, a constant gas flow or a gas with the least variable flow speed may be desirable and contemplated herein to avoid film ruptures.

The vacuum chamber may be a part of a EUV scanner. It may have a direct connection with a EUV scanner as a part, an accessory, or an attachment of a EUV manufacturing assembly line. It may also be stand-alone for performing such annealing treatment near a scanner or remotely.

Annealing process may start with a nanofiber structure being mounted on a frame and then placed directly in an annealing chamber or a container. This chamber is pumped down to or near a vacuum at a level of about 104 torr or less. The chamber is then heated to a predetermined temperature. At this point, pellicles are placed in the chamber for a selected duration. Pellicles may be placed in the chamber before the heating is initiated. After the chamber returns to room temperature and atmospheric pressure with or without a cooling gas, such as argon, the process is complete, and pellicles can be stored in ambient conditions, in a vacuum, in inert gas, or a combination thereof to avoid contamination, exposure to atmospheric air other gases for possible oxidation, or damage.

Annealing may be performed under electromagnetic irradiation with a single wavelength, which is typically drawn in a bell shape curve (a single peak) on a graph. Annealing may further include electromagnetic energy from a combination of multiple electromagnetic waves with non-overlapping peaks and/or overlapping peaks, with each peak representing a particular electromagnetic energy source. Multi-wavelength radiation may deliver sufficient electromagnetic energy to a target, which may accelerate the annealing processes with reduced annealing time for the mass production of pellicle products.

Electromagnetic energy may be delivered in a continuous mode or a flash mode (e.g., a flash of light that may last as short as 0.1 ms). The electromagnetic energy delivered in the flash mode (which may be referred to as flash light) may anneal or re-anneal a pellicle film prior to undergoing an EUV lithography process or post an EUV lithography process. Specific settings for the electromagnetic energy delivery may depend on, but not limited to, the target material density, porosity, thickness, and microstructural geometry.

Each flash light may cover a side of an entire lithography pellicle film with little irradiation variation for even annealing results. One or more other flash lights may shine opposite side of the pellicle film. For flash light annealing with two or more rounds of flash light irradiations, changing, adjusting, or rotating target film positions with respect to the flash light source may avoid possible irradiation bias or unevenness.

The term annealing may include further aspects and broader interpretations in various technical fields and industries applicable to or related to the current disclosure. One or more present innovative contributions herein arise for the material science and semiconductor fields.

### Film Formation and Thermal Annealing

An ultra-thin and ultra-low density CNT pellicle film may be produced, followed by a thermal annealing process in accordance with exemplary embodiments of the current disclosure.

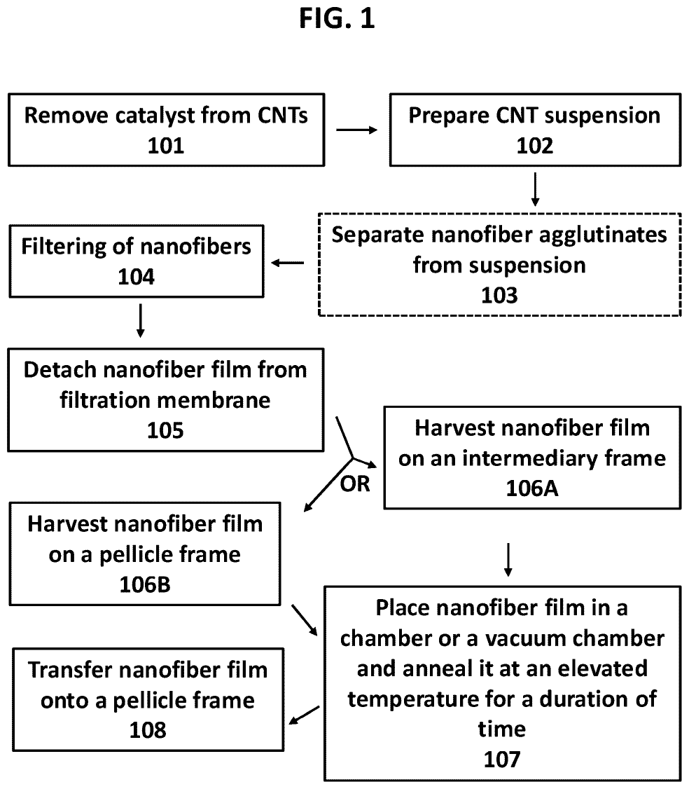

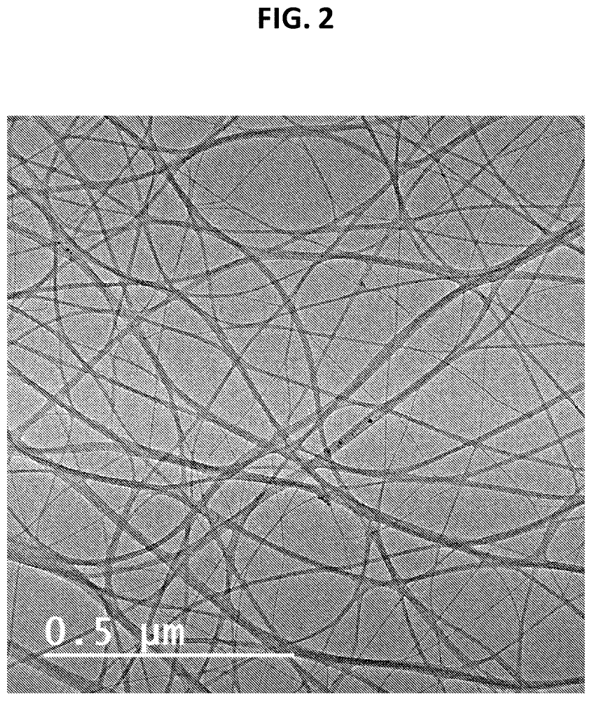

FIG. 1 illustrates a filtration method for forming a pellicle film, as shown in FIG. 2, followed by a subsequent annealing treatment in accordance with an exemplary embodiment.

Another embodiment of this disclosure may further include any pellicle films produced, to be produced, processed, or to be processed by all means prior to an annealing treatment. Furthermore, another embodiment of the present disclosure includes any other pellicle films with various CNT surface modifications, including but not limited to coating or other means of one or more metal elements, metal oxides, CNT surface modifiers, or a combination thereof.

As illustrated in FIG. 1, a free-standing carbon nanotube-based pellicle film may be produced via a filtration-based method. In Operation 101, catalysts are removed from carbon nanotubes (CNTs) that are to be used to form a water-based suspension. In an example, prior to dispersion into a suspension, the CNTs may be chemically purified to reduce a concentration of catalyst particles to less than 1% or preferably less than 0.5% wt., which may be measured by, for example, thermogravimetric analysis. Removal of the catalysts is not limited to any particular process or procedure, such that any suitable process may be utilized to achieve a desirable result.

In Operation 102, a water-based suspension is prepared using the purified CNTs, such that the purified CNTs are evenly dispersed in the water-based suspension. When preparing one or more CNT suspensions, carbon nanotube material can be mixed with a selected solvent to distribute nanotubes uniformly in a final solution as a suspension. Mixing can include mechanical mixing (e.g., using a magnetic stir bar and stirring plate), ultrasonic agitation (e.g., using an immersion ultrasonic probe), or other methods. In some examples, the solvent can be a protic or aprotic polar solvent, such as water, isopropyl alcohol (IPA), and aqueous alcohol mixtures, e.g., 60%, 70%, 80%, 90%, 95% IPA, N-Methyl-2-pyrrolidone (NMP), dimethyl sulfide (DMS), and combinations thereof. In another example, a surfactant can also be included to aid the uniform dispersion of carbon nanofibers in the solvent. Examples of surfactants include, but are not limited to, anionic surfactants.

Carbon nanofiber films are generally formed from one of MWCNTs, DWCNTs, or SWCNTs. A carbon nanofiber film may also include a mixture of different types of CNTs (i.e., SWCNTs, DWCNTs, and/or MWCNTs) with a variable ratio between the different types of CNTs. Other types of CNTs may also be used to produce CNT films by filtration and other known and contemplated methods.

Each of these three different types of common carbon nanotubes (e.g., MWCNT, DWCNT, and SWCNT) has different properties. In one example, single-wall carbon nanotubes can be more conveniently dispersed in a solvent (i.e., with the majority of nanotubes suspended individually and less adsorbed onto other nanotubes) for subsequent formation into a sheet of randomly oriented carbon nanotubes. This ability of individual nanotubes to be uniformly dispersed in a solvent can, in turn, produce a more planarly uniform nanotube film formed by removing the solvent from the suspended nanofibers. This physical uniformity can also improve the uniformity of other properties across the film (e.g., transparency and scattering to irradiation, mechanical strength upon pressure changes, and lifetime/durability test).

In an example, the water-based CNT suspension in Operation 102 may have at least above 85% purity of SWCNTs. The remaining may be a mixture of DWCNTs, MWCNTs and/or a catalyst. In other examples, a dispersed CNT suspension with various ratios of different types of CNTs may be prepared, such as about 20%/75% DWCNTs/SWCNTs, about 50%/45% DWCNTs/SWCNTs, about 70%/20% DWCNTs/SWCNTs, with MWCNTs accounted for the remaining. A mixture of 10% or more MWCNT and a blended DWCNT and SWCNT at various DWCNT/SWCNT percentage ratios may be prepared and subjected to the same filtration process of forming nanofiber structures. In an example, anionic surfactants may be utilized as the dispersants in the suspension to enhance the uniform dispersion of different types of CNT mixtures.

In Operation 103, the CNT suspension is then further purified to remove the aggregated or agglutinated CNTs from the initial mixture. In an example, different forms of CNTs, undispersed or aggregated vs. fully dispersed, may be separated from the suspension via centrifugation. Centrifugation of surfactant-suspended carbon nanotubes may aid in decreasing the turbidity of the suspension solution and ensuring a complete dispersion of the carbon nanotubes in the final suspension solution before going into the next filtration step. However, aspects of the disclosure are not limited thereto, such that other separation methods or processes may be utilized. According to exemplary aspects, Operation 103 may be optionally performed or performed as a necessary step in the formation of the pellicle film.

In Operation 104, any CNT suspension, preferably the CNT supernatant after a separation procedure from Operation 103, is then filtered through a filtration membrane to form a CNT nanostructure film, a continuous sheet of film of intersecting CNTs.

In an example, one technique for making the CNT film uses water or other fluids to place nanotubes in a random pattern on a filter, often a flat filtration membrane. The evenly dispersed CNT-containing mixture is allowed to pass or is forced to pass through the filter, leaving a nanofiber structural layer on the surface of the filter. The size and shape of the resulting films are determined by the size and shape of the desired filtration area of the filter, while the thickness and density of the films are determined by the quantity of nanofiber material applied during the filtration process and the permeability of the filtration membrane to each ingredient of the input material, as the non-permeable ingredient is captured on the surface of the filter. If the concentration of nanofibers dispersed in the flow-through filtration fluid is known, the mass of nanofibers deposited onto the filter can be determined from the amount of such fluid that passes through the filter, and the film's areal density is determined by the nanofiber mass divided by the total filtration area. And filtration area of the filter may be the same or smaller than the size of the filter, depending on the filter's underlying supporting structure. The selected filter is generally not permeable to any CNTs.

The filtration-formed CNT film may be of a combination of SWCNT, DWCNT, and/or MWCNT in differing compositions. Carbon nanofibers may become intersected randomly to form an interconnected network structure in a planar orientation to form a thin CNT film.

In Operation 105, the resulting CNT film is then separated from the filtration membrane, starting from a first edge of the CNT film toward a second edge, nonsignificantly overlapping with the first edge. When detached fully from the filtration membrane, the nanofiber film is ready for the next operation, which may be either Operation 106A or Operation 106B.

In Operation 106A, the detached CNT film is harvested onto a solid substrate, such as a frame, sometimes referred to as a harvesting frame, a harvester frame, or an intermediary frame. The detached CNT film may be harvested directly and mounted onto a pellicle border, which has a defined aperture.

Alternatively, in Operation 106B, the CNT film may be harvested and mounted to the pellicle border. The CNT film may cover the entire aperture to form a pellicle or pellicle device, ready for EUV photolithography. The detached CNT film may be mounted on any frame (e.g., a metal frame, silicon frame, quartz frame, or a pellicle border) with an opening of as small as 5 mm×5 mm. A much larger size film, 110 mm×140 mm or greater, is in high demand, serving as a full-size pellicle film for an actual EUV scanner. CNT film characterization, such as an optical light transmittance and/or transmittance uniformity (or variation) test, EUV transmittance and/or transmittance uniformity (or variation) test, mechanical strength, deflection test, permeability test, deflection at constant pressure or during simulated scanner pumping down conditions, lifetime test, particle test, may be performed. A full-size pellicle for EUV lithography scanning may require an ultra-thin, free-standing film generally larger than 110 mm×140 mm, based on current industry standards. A full-size pellicle may be referred to as a full-field pellicle.

A pellicle frame referred to herein may tolerate high-temperature treatments to sustain high-temperature annealings. Furthermore, it may have a low thermal expansion coefficient to avoid stretching or cause stretching of the nanofiber films mounted on itself. Exemplary frame material can be selected from silicon dioxide, commonly known as quartz, silicon carbide, etc.

In Operation 107, a CNT film on a frame, pellicle border, or intermediate transferring frame, receives a thermal annealing treatment. A thermal annealing treatment is conducted by placing the CNT film in a closed chamber or a vacuum chamber at a predetermined elevated temperature for a specified treatment duration. However, aspects of the present disclosure are not limited thereto, such that various thermal annealing treatment methods may be conducted at different temperatures, for different periods of time (duration), and by different thermal energy sources, e.g., different electromagnetic wavelengths or wavelength ranges.

In an example, the thermal annealing treatment may be conducted at a target temperature of about 500° C. and above, about 600°° C. and above, 700° C. and above, 800° C. and above, 900° C. and above, and less than about 3,000° C., 2,500° C., 2,000° C., or 1,500° C. The actual annealing temperature preferably stays constant, but it may fluctuate in a range of 1-10% above and below the predetermined target temperature measured inside an annealing chamber or close to an annealing target, i.e., a pellicle film. For a target temperature of 600° C., the actual temperature may be measured at 540° C. to 660° C.

Also, in another example, the thermal annealing treatment may be conducted between 1 second to 60 minutes at a target temperature or temperature range. Preferred treatment duration may be between 10 minutes and 30 minutes. However, aspects of the present disclosure are not limited thereto, such that annealing by a flash of light may last as short as 0.1 millisecond.

In another example, annealing treatment may be performed in a chamber with an annealing chamber pressure at atmospheric pressure, in a vacuum, or between both. The annealing treatment chamber generally supports the distribution of thermal energy, preferably an even distribution throughout the entire chamber. Thermal energy may be directed toward a target or targets, such as one or more CNT films. It may also diffuse within the chamber, immerse one or more films, and treat the entire set of pellicle films evenly with less or no variation. Any annealing variation, such as uneven energy deposited on a film, or uneven energy received at the film, may cause, for example, film wrinkles, focal film thickening or thinning, premature film breakage, etc. Any of these events or changes can alter film light transmission rates, worsen transmission variation, weaken film mechanical strength, and shorten film lifetime.

After annealing, a pellicle film may be ready for EUV lithography. In Operation 108, the annealed CNT film or nanofiber film is transferred onto a pellicle frame.

An annealed film, being placed on an intermediary frame prior to annealing, may be further analyzed by, including but not limited to, a visible light (e.g., 550 nm wavelength) and EUV transmission measurement, visible light and EUV transmission variation measurement, coating, mechanical tension measurement and adjustment of the film, or transferred to a pellicle border.

### EUV Transmission Enhancement and Scattering Reduction by Annealing

It has been known that transmission rates for a selected material measured by a given light source in a visible wavelength are not the same as the transmission rates of extreme ultraviolet light (EUV). For example, a CNT film produced from Operation 101 to Operation 106A or 106B, without Operation 107, having approximately 80% transmission rate when measured at a 550 nm wavelength, may yield a transmission rate at EUV 13.5 nm of about 94%. This observation, together with reports from others, leads to difficulties and uncertainties in predicting and correlating transmission rates for a given material at selected visible and EUV wavelengths. Without further experimentation, it may be very difficult or nearly impossible to establish the correlations between the transmission rates at these wavelengths. Upon further treatment or modification imposed on the pellicle film, the predictability of such correlations will become even more challenging.

An exemplary embodiment of the present disclosure covers an annealing-treated CNT pellicle film, having a EUV transmission rate elevated and a scattering rate lowered when compared to untreated CNT pellicle film. The annealed CNT pellicle films exhibit little physical property changes. Further, EUV transmission variation (i.e., differences of multiple EUV transmission rates measured at various locations of a pellicle film) may remain unchanged or have little change after annealing. These improvements are unexpected and are different from known prior art.

While the exemplary embodiments of the present disclosure meet or exceed EUV pellicle requirements, including, but not limited to, EUV transmission rate, EUV transmission evenness, deflection rate, and mechanical strength of films under pressure changes, the exemplary embodiments also provide a method to treat pellicle films other than CNT pellicle film or majority DWCNT pellicle film, which may be inferior to industrial standards, and enhance their properties to meet or exceed a minimum EUV pellicle requirement. For example, a film with a EUV transmission rate of less than 92% may exceed a transmission rate of 92% or even higher than 95% after applying one or more aspects of the present disclosure.

This constitution of the exemplary pellicle film provides an ultra-thin pellicle film, which allows for high EUV transmission rates (e.g., greater than 70%, 80%, 85%, 90%, or 92%) while being extremely temperature resistant (e.g., resistant to temperatures above 500° C.) and mechanically robust to sustain humans and robotic maneuvers and disturbances, including but are not limited to packaging, shipping, atmospheric pressure fluctuations at low and high altitude, and pressure changes during EUV scanner pumping down and venting. In an example, a minimum EUV transmission rate may be a value of 80% and a preferred EUV transmission rate of 90% or greater.

Table 1 shows exemplary annealing effects on EUV transmission rates exhibited by a pellicle film formed by exemplary embodiments of the present disclosure. In the below-noted example, CNT pellicle film samples were mounted on quartz frames and annealed under a vacuum of less than 104 torr for 10 minutes at 600° C. in a tubular heating oven. They were stored at ambient temperate in a sealed environment filled with argon until the time of an EUV transmission test.

TABLE 1
Annealing Effects on EUV Transmission Rates

| | No | | 1-week post | 1-month post | 3-month post | Instant |
|---|---|---|---|---|---|---|
| | Annealing | Annealing | annealing | annealing | annealing | enhancement |
| EUV T % | 93.88 | 96.00 | 95.90 | 95.36 | 94.64 | 2.12 |
| Scattering | 0.081 | 0.065 | 0.066 | 0.077 | 0.078 | 0.016 |
| (degree) | | | | | | |

Exemplary CNT pellicle films noted above exhibited approximately 80% transmission rate measured at 550 nm wavelength and a mean EUV transmission rate of about 93.88% using a 9-point measurement per sample prior to performing annealing. After annealing the same samples, tests were performed immediately. The transmission rates measured at 550 nm wavelength did not show a statistical difference, and instead remained almost the same as the original values. The average EUV transmission rate from a 9-point measurement was about 96.00%, or about a 2.12% increase. The same pellicle films were stored under ambient conditions, and the EUV transmission measurements took place one week, one month, and three months post the annealing treatment with readouts of EUV transmission rates based on 9-point per sample measurement at 95.90%, 95.36%, and 94.64%, respectively (see Table 1). This study demonstrates that a film with less than 94% EUV transmission rate may gain EUV transmission, reach an EUV transmission rate of 95% and higher, and maintain a satisfactory EUV transmission rate within two to three months after annealing treatment. The EUV transmission gain may not experience significant loss during the testing period under normal storage conditions and without special equipment. Three months after the annealing treatment, a significant portion of EUV transmission gain remains with a transmission rate above 94.5%. Enhancing EUV transmission by annealing may transform thicker films, which may not be qualified for EUV photolithography initially due to published EUV pellicle standards, into EUV pellicles for actual EUV lithography.

Another main challenge in EUV lithography is the presence of flare, which is the unwanted total integrated light scattering at a wafer level. Flare reduces the critical dimension and imaging performance for EUV printing. Therefore, controlling or lessening pellicle film scattering is important for effective EUV photolithography.

As shown above in Table 1, the scattering results are also improved by at least one of the embodiments of the present disclosure. Annealing reduces pellicle film scattering from 0.0811% to 0.0645% measured at the 4.7° (degree) angle. This scattering reduction was partially lost when measured one month after the treatment. However, such scatting improvement does not disappear entirely after 3-month storage under ambient conditions.

The results as shown in Table 1 demonstrates the strong potential of applying an annealing treatment in EUV pellicle film production with unexpected but effective EUV transmission enhancement.

### Effects of Repeating Annealing Treatment

Another embodiment of the present disclosure relates to repetitive annealings to raise EUV transmission rates after an initial EUV transmission enhancement by annealing and a subsequent EUV transmission enhancement reduction. For example, the EUV transmission rate of a pellicle film measured one month (or four weeks) after the first annealing treatment was 95.36% (see Table 1). It was stored under ambient conditions in atmospheric air for one more week, then was annealed again, which was five weeks after the primary annealing, and its EUV transmission rate was measured again with a readout of 95.97%, a gain of about 0.6% EUV transmission.

This second annealing performed at the five-week time point reversed the gradual loss of gained EUV transmission and raised the EUV transmission once again. This strategy of applying secondary annealing treatments after primary annealing with sustained storage time may recover lost EUV transmission and further enhance EUV transmission.

The data presented herein may further provide a method of applying annealing treatment of an annealed nanofiber pellicle film or CNT pellicle film prior to subjecting the pellicle film to EUV exposures and a method of applying re-annealed pellicle to EUV scanners.

However, aspects of the present disclosure are not limited to the two annealing treatments, such that more annealing treatments may be performed. An exemplary embodiment may include subsequent annealing up to a total of ten annealing treatments.

### Effects of Gas Type on EUV Transmission Enhancement

It was reported previously that in the field of EUV lithography, both hydrogen ions and hydrogen radicals cause broken carbon-carbon bonds in carbon nanotubes, i.e., carbon etching effects. Annealing in the presence of hydrocarbon gases may repair these broken bonds.

As demonstrated above, the thermal annealing of the present disclosure increases EUV transmission when annealing reactions are performed without any gases or in a vacuum chamber. However, the embodiments of the present disclosure are not limited to vacuum-dependent treatment. They include annealing treatments in the presence of one or more selected gases. Table 2 illustrates the experimental results from two exemplary types of gases.

TABLE 2
Effects of Different Gas Types Applied in Thermal Annealing

| | Transmission Rate at 550 | | Transmission Rate at 550 | |
|---|---|---|---|---|
| Gases in | nm (%) (Before Annealing) | | nm After annealing (%) | |
| Thermal | | Standard | | Standard |
| Annealing | Mean | Deviation | Mean | Deviation |
| Nitrogen | 80.08 | 0.54 | 81.62 | 0.77 |
| Argon | 79.94 | 0.64 | 80.38 | 0.24 |

The pellicle films, in accordance with Operations 101 to 106A/B of FIG. 1, were treated at 650° C. in the presence of a representative gas, nitrogen or argon, for 30 minutes. Their results are listed in Table 2. The nitrogen annealing showed meaningful transmission gain from 80.08±0.54% to 81.62±0.778% measured at 550 nm wavelength, while the argon treatment did not (measurement results: 79.94±0.64% before annealing and 80.38±0.24% after annealing).

Nitrogen is a common chemical element and can be found in a variety of materials. Nitrogen gas is generally considered not active as an inert gas. This non-reactivity is true at a low-temperature setting. However, it becomes reactive at a higher temperature, becoming oxidative because the unregulated flow of nitrogen at a high temperature can lead to nitride formation, which may react to or modify the surface of a material. Avoidance of nitride formation may turn nitrogen gas into a good candidate gas, which may be incorporated into one of the embodiments of the present disclosure.

Argon is another common chemical and inert gas known for its stability in a wide range of temperatures. Argon annealing does not alter the transmission of the tested films measured at 550 nm, according to information provided in Table 2.

The results from Table 2 demonstrate that some inert gas may cause changes in CNT material (or other material), resulting in alterations in visible light transmission. Other inert gases, such as argon, may retain the properties of CNTs in light transmission and subsequently enhance EUV transmission rates. Thermal annealing in accordance with one of the embodiments may utilize one or more carefully selected inert gases for EUV transmission enhancement in a way similar to vacuum-based thermal annealing.

### Effects of Annealing on Films of Different Densities

Embodiments of the present disclosure include thermal annealing on pellicle films produced in accordance with Operations 101-106A/B of FIG. 1 with different film areal densities. Each film has a uniform areal density with an EUV transmission rate that is equal, superior, or inferior to EUV pellicle requirements. A film's areal density is defined as a finite amount of material on a rendered surface area. In this case, an areal density of the film produced by a filtration process is determined by a nanofiber quantity or nanotube mass divided by a total filtration area. Pellicle films with different areal densities may be produced based on the aforementioned Operations of FIG. 1 and principles. Once harvested onto a frame, a free-standing film's transmittance at 550 nm or EUV can be determined.

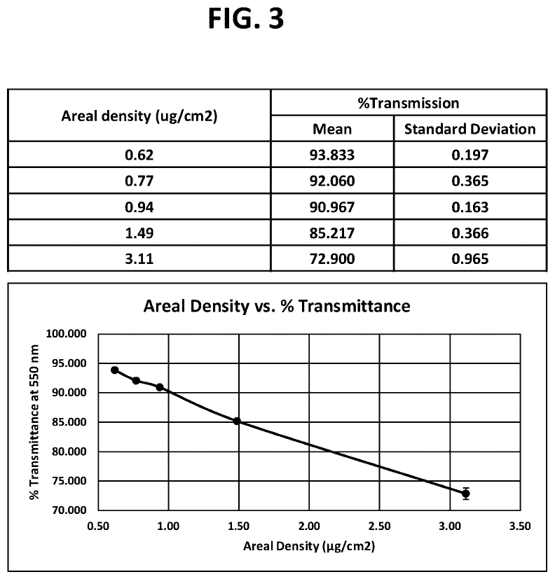

FIG. 3 illustrates the correlation between areal densities and film transmission rate at 550 nm in accordance with an exemplary embodiment.

As exemplarily provided in FIG. 3, an areal density value of 0.62 μg/cm² may result in a mean 550 nm transmission rate of 93.833% with a standard deviation of 0.197%. Further, an areal density value of 0.77 μg/cm² may result in a mean 550 nm transmission rate of 92.060% with a standard deviation of 0.365%. Also, an areal density value of 0.94 μg/cm² may result in a mean 550 nm transmission rate of 90.967% with a standard deviation of 0.163%, and an areal density value of 1.49 μg/cm² may result in a mean 550 nm transmission rate of 85.217% with a standard deviation of 0.366%. Lastly, an areal density value of 3.11 μg/cm² may result in a mean 550 nm transmission rate of 72.900% with a standard deviation of 0.965%.

Areal densities of any CNT films are not limited to the list in FIG. 3. A high areal density film may have a density of 6.0 μg/cm2 or above. A low areal density film may have a density at low as 0.2 μg/cm2 for a transmittance of around 98%.

Table 3 lists EUV transmission test results of CNT films having different 550 nm transmission rates before and after exemplary thermal annealing.

TABLE 3
Annealing Effects of Films with Different Thickness

| | EUVT (%) | EUVT (%) | |
|---|---|---|---|
| Film Transmission | (without | (post- | Instant EUVT |
| rate @ 550 nm | annealing) | annealing) | Gain (%) |
| 93.9% | 98.2 | 98.6 | 0.4 |
| 80.4% | 93.9 | 96.0 | 2.1 |
| 70.0% | 90.0 | 93.0 | 3.0 |

Determined by 550 nm wavelength, an exemplary film of about 93.9% transmission rate has 98.2% and 98.6% average EUV transmission rates before and after annealing from 9-point EUV transmission rate measurements. Another exemplary film of about 80.4% transmission rate has 93.9% and 96.0% average EUV transmission rates before and after annealing. Yet another exemplary film of about 70.0% transmission rate has 90.0% and 93.0% EUV transmission rates before and after annealing. These three films have respective instant EUV transmission rate gains of 0.4%, 2.1%, and 3.0% after annealing. As provided in Table 3, the thicker the film, based on the lower 550 nm transmission rates, the higher magnitude of the EUV transmission gain may be observed.

Another embodiment of the present disclosure includes selecting a film with about 50% transmission rate and above measured at 550 nm, treating the film by annealing in accordance with one of the embodiments, and performing a EUV transmission measurement with a target EUV transmission rate at about 90% or above.

An embodiment of the present disclosure further includes selecting a film with a thickness from 3 nm to 200 nm or transmission rate measured at 550 nm between 50% and 95%, performing thermal annealing, and targeting an annealed film to achieve an EUV transmission rate between 90% to 99%.

As a result of the above demonstration, annealing provides an effective approach to confer unexpected new values and previously unknown features to existing nanofiber pellicle films. It contemplates solutions to hard-to-overcome issues facing ultra-thin, ultra-low-density nanofiber pellicle films. For example, a thicker film or a film with higher areal density may arrive at a given lithography scanner with eased transportation challenges and/or reduced transportation-caused damage and receive an annealing treatment to raise its EUV transmission rate to a desired level for EUV lithography.

### Effects of Annealing Temperature on EUV Transmission Enhancement

It is known that annealing requires an elevated temperature, i.e., above an ambient temperature, during the process. High-temperature annealing, as shown above, demonstrates significant EUV transmission enhancement either in a vacuum or under atmospheric pressure in the presence of an inert gas, such as argon. However, proper annealing conditions are critical to enhance CNT pellicle film's EUV transmission rates, maintain the stability of the film, maximize such enhancement without excessive treatments and heating energy consumption, and avoid possible pellicle lifetime reduction.

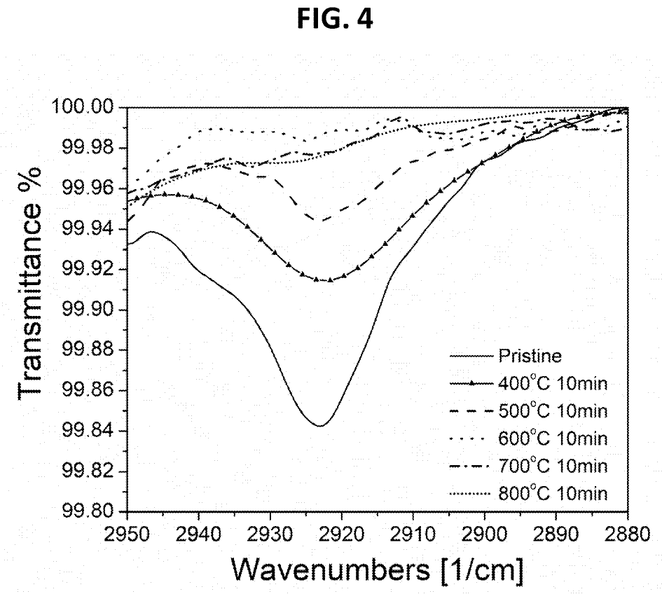

FIG. 4 illustrates the effects of different annealing temperatures from the results of Fourier-transform infrared spectroscopy (FTIR) studies in accordance with an exemplary embodiment.

FTIR spectroscopy measures how much light a target sample, such as a liquid, a gas, or a solid, absorbs at each wavelength over the infrared spectrum. A sample material absorbs a portion of infrared radiation due to its chemical properties, compositions, and structural conformation at molecular levels, while other radiation passes through and may reach detectors for recording. A computer analyses the recorded raw data, called an interferogram, and arranges and displays corresponding light absorption or transmittance at each wavelength in a diagram. For a given sample material, it has its representative data set and a computer-generated curve in a graph, like a fingerprint. When the same material is modified, its light absorption characteristics may change due to alterations in its structure, chemical compositions, chemical residues, and the resulting molecular vibrations. These changes will draw up a new data set or new curve. Comparing the data collected before and after annealing may reveal changes occurred and/or accumulated within the sample material, which correlate with different measurements from the same sample treated in the same way.

When studied in addition to EUV transmission measurements (see Tables 1 and 2), differences observed by FTIR may represent the same modifications inside a nanofiber pellicle film.

According to exemplary aspects, carbon nanotubes are formed by wrapping one or more layers of graphene sheets consisting of carbon and hydrogen atoms. Each graphene sheet is a layer of carbon atoms bonded together in a hexagonal (honeycomb) mesh. For a given CNT type, SWCNT, DWCNT, or MWCNT has its own features in its FTIR spectrum. A CNT pellicle film may have one or mixed types of CNTs, its FTIR spectrum data may be unique and unidentical to a spectrum collected from a pure CNT type. However, when the CNT population within the pellicle film is modified and/or carbon and hydrogen atom interactions, e.g., chemical bonds, within the CNTs are changed, the pellicle film's spectrum may change according to what happens to itself chemically or structurally. At a molecular level, aliphatic hydrocarbon residues are altered, which may be detected by FTIR.

FIG. 4 shows the FTIR study results of the effects of different annealing temperatures on the pellicle films prepared in accordance with Operations 101 to Operation 107, in which 400° C., 500° C., 600° C., 700° C., and 800° C. target temperatures are applied for 10 minutes with an untreated pristine sample as a negative control. The FTIR spectra of FIG. 4 depict the measurement results between 2950 to 2850 cm-1 wavenumber. Data outside this 2950 to 2850 cm⁻¹ wavenumber range may not show any meaningful difference (data not shown). A wavenumber is the spatial frequency of a wave, measured in cycles per unit distance, and, as used in spectroscopy, defined as the number of wavelengths per unit distance, typically centimeters (cm⁻¹).

The graph in FIG. 4 indicates significant differences in the light transmittance upon different annealing temperatures. The transmittance percentages show insignificant differences between 2950 to 2850 cm−1 wavenumber for annealing treatments at 600° C., 700° C., and 800° C., judging individual curves in the graph. The 400° C. and 500° C. treatments have much lower transmittance, however, higher than the pristine unannealed sample (see the dips around wavenumber 2920). As shown in Table 1 above, the same 10-minute annealing treatment at 600° C. raises the EUV transmission rate. Combining with the FTIR results of FIG. 4, the 700° C. and 800° C. treatments may have the same effects as the 600° C. treatment, while the 400° C. and 500° C. annealing may not conclude the same. The provided FTIR analyses in the instant wavenumber range indicate chemical changes, potentially involving carbon atoms. Such changes contribute to EUV transmission enhancement exemplarily embodied in the present disclosure.

FTIR may be a powerful alternative to direct EUV transmission measurement. An annealing temperature of 600° C. or above, within a possible 10% variation, may be required to derive a stable nanofiber pellicle film with a much-needed EUV transmission enhancement from a pristine pellicle film.

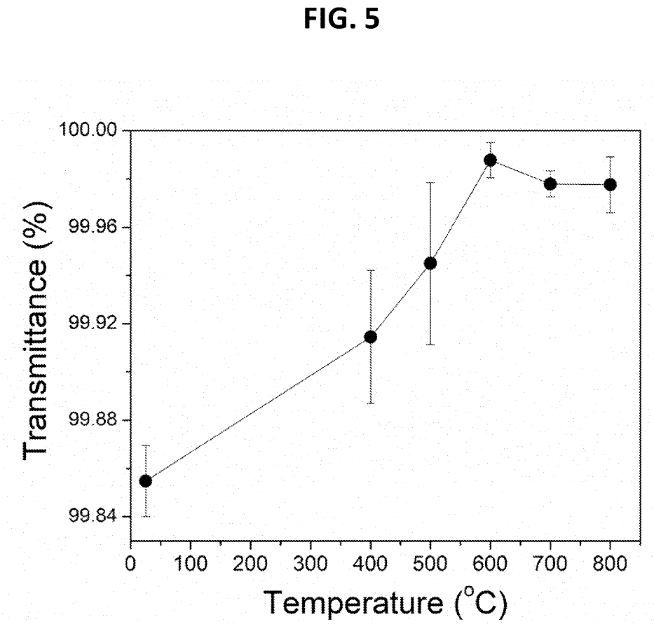

FIG. 5 depicts the transmittance in percentage measured at 2920 wavenumber from FIG. 4, which further illustrates the effectiveness of various temperatures in annealing as described above. As provided in FIG. 5, the 600° C. treatment yields the best results and plateaus thereafter.

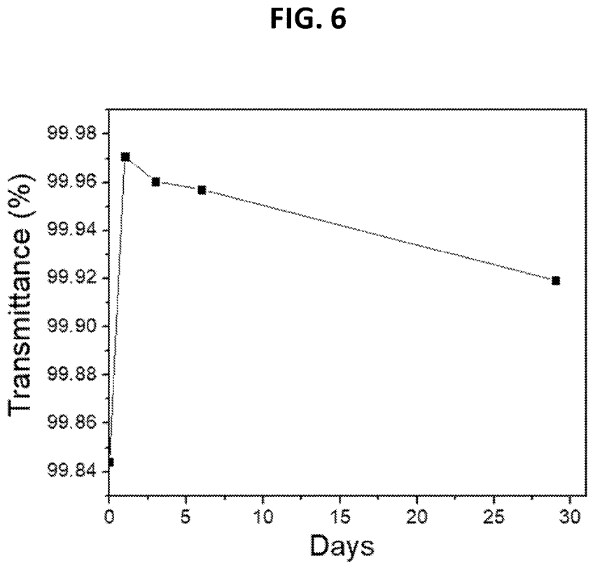

Repeating the same study as shown in Table 1, the measurements at 2920 wavenumber by FTIR were taken on Day 1, Day 3, Day 5, and Day 30 after the annealing, and the results were summarized in FIG. 6. The initial transmittance jump or gain on Day 1 was partially lost over a period of one month. The results by FTIR resemble the correlation between thermal annealing and EUV transmission enhancement from Table 1.

Another embodiment of the present disclosure includes applying a higher effective annealing temperature with a shorter annealing duration. It provides implementation flexibility for pellicle film production. Exemplary films in accordance with Operations 101-106A/B were annealed at 700° C. for 10 min having insignificant difference measured by FTIR when compared to samples annealed at 600° C. for 30 min.

### Annealing Duration for EUV Transmission Enhancement

Annealing time may be 5 min or less at a selected annealing temperature. Other annealing treatments may take place at a selected temperature for 30 minutes or more. Annealing time or annealing duration may be divided into a plurality of annealing moments or irradiation moments with respect to electromagnetic wave irradiation for the purpose of analyzing annealing treatment at any given time during the annealing processes.

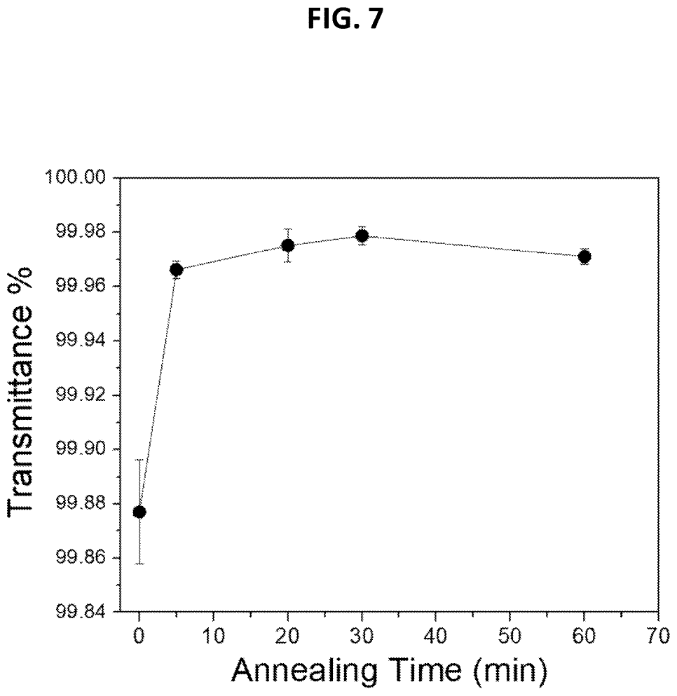

FIG. 7 depicts the effects of annealing duration (or annealing time) on changes in light transmittance percentage based on FTIR studies. CNT pellicle films with 80% transmittance at 550 nm were annealed at 650° C. for different time intervals. A 5-minute-annealing regimen may be sufficient for EUV transmittance enhancement. A 20-minute or 30-minute annealing may improve transmittance further, but the improvement is less drastic compared to the effect from the very first 5-minute annealing. Further extended treatment duration may not show additional benefits.

However, aspects of the present disclosure are not limited thereto, such that a flash light annealing may be as short as 0.1 ms.

Although the above-noted disclosure was provided with respect to CNTs, aspects of the present disclosure are not limited thereto, such that different nanotube films, such as boron nitride nanotubes (BNNT), nanofibers, or nanofibers arranged within a film by different methods, other than filtration, or in different orientations, may be utilized by the same principle.

The above-mentioned thin films may also be conformally coated by various methods before or after annealing treatment. The coating method includes, without limitation, e-beam, chemical or physical vapor deposition, atomic layer deposition, spin coating, dip coating, spray coating, sputtering, DC sputtering, and RF sputtering. Coating material may be selected from any one of the following, silicon, SiO₂, SiON, boron, ruthenium, boron, zirconium, niobium, molybdenum, rubidium, yttrium, YN, Y₂O₃, strontium, rhodium, or a combination thereof. The material may also be any one or more metals, metal oxides or nitrides, or a combination thereof. However, aspects of the present disclosure are not limited thereto, such that a combination of materials may be used in the coating.

The illustrations of the embodiments described herein are intended to provide a general understanding of the various embodiments. The illustrations are not intended to serve as a complete description of all of the elements and features of products and methods that form the products or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A nanostructure film comprising:
a plurality of carbon nanofibers that are intersected randomly to have an interconnected network structure, the interconnected network structure having a planar orientation and being annealed with a post-annealing extreme ultraviolet (EUV) transmission rate of 90% and above.

2. The nanostructure film of claim 1, wherein the post-annealing EUV transmission rate is 92% and above.

3. The nanostructure film of claim 1, wherein the post-annealing EUV transmission rate is 95% and above.

4. The nanostructure film of claim 1, wherein the post-annealing EUV transmission rate is at least 0.4% higher than a pre-annealing EUV transmission rate of the interconnected network structure.

5. The nanostructure film of claim 1, wherein the annealing applies at least one electromagnetic wave irradiating on at least one side of an entire interconnected network structure for at least one irradiation moment, the at least one irradiation moment being a timepoint during the annealing.

6. The nanostructure film of claim 5, wherein a collection of the at least one electromagnetic wave covers the at least one side of the entire interconnected network structure evenly for the at least one irradiation moment.

7. The nanostructure film of claim 5, wherein the at least one electromagnetic wave is selected from 10 nm to 1 mm.

8. The nanostructure film of claim 1, wherein the interconnected network structure is annealed at least a second time or more.

9. The nanostructure film of claim 1, wherein the second annealing raises the EUV transmission rate of the interconnected network structure by at least 0.6%.

10. The nanostructure film of claim 1, wherein the interconnected network structure has a reduced EUV scattering posting annealing.

11. A method of improving an extreme ultraviolet (EUV) transmission of a EUV pellicle film, the method comprising:
providing a plurality of intersecting carbon nanofibers having an interconnected network structure;
irradiating a first time at least one entire side of the interconnected network structure with one or more electromagnetic waves for at least one irradiation moment; and
enhancing a percentage of a EUV transmission rate by at least 0.4%, wherein a cumulation of the at least one irradiation moment span an irradiation duration.

12. The method of claim 11, wherein the one or more electromagnetic waves deliver electromagnetic energy covering the at least one entire side of the interconnected network structure evenly at the irradiation moment.

13. The method of claim 11, wherein the one or more electromagnetic waves raise a temperature to a degree selected from 540° C. to 3000° C. and hold the temperature for the irradiation duration.

14. The method of claim 11, wherein the irradiation duration is selected between 0.1 millisecond to 60 minutes.

15. The method of claim 11, wherein the irradiating occurs in a chamber with a pressure setting ranging from a vacuum pressure to an atmospheric pressure.

16. The method of claim 15, wherein the chamber receives a gas flow, the gas being an inert gas and altering a post-irradiation visible light transmission rate of the interconnected network structure insubstantially.

17. The method of claim 15, further comprising:
connecting the chamber directly with a EUV lithography scanner.

18. The method of claim 11, further comprising:
storing the interconnected network structure in an inert gas environment or in a vacuum.

19. The method of claim 11, further comprising:
repeating the irradiating a second time or more, and enhancing the EUV transmission rate of the interconnected network structure.

20. The method of claim 19, wherein the enhanced EUV transmission rate is at least 0.6% higher.

21. The method of claim 11 further comprising:
performing the irradiating prior to subjecting the plurality of the intersecting carbon nanofibers having the interconnect network structure to an EUV lithography process.

22. The method of claim 11, further comprising:
performing the irradiating remotely from an EUV lithography scanner.

23. The method of claim 11, wherein the one or more electromagnetic waves have a wavelength selected from 10 nm to 1 mm.
